(19) United States
(12) Patent Application Publication
(10) Pub. No.: US 2026/0150242 A1
(43) Pub. Date: May 28, 2026

(54) SYSTEMS, DEVICES, AND METHODS FOR EFFICIENT HEAT MANAGEMENT

(71) Applicant: FORCED PHYSICS LLC, Scottsdale, AZ (US)

(72) Inventor: Scott S. DAVIS, Fountain Hills, AZ (US)

(21) Appl. No.: 19/122,553

(22) PCT Filed: Oct. 20, 2023
(86) PCT No.: PCT/US2023/077386

§ 371 Date: Apr. 18, 2025

Related U.S. Application Data
(60) Provisional application No. 63/380,381, filed on Oct. 20, 2022.

(51) Int. Cl. H05K 7/20

(52) U.S. Cl. CPC H05K 7/20336; H05K 7/20809

(57) ABSTRACT

Systems, methods, and devices are provided for extended thermal transfer from a heat plane. Consistent with this disclosure, a device can include at least one cooling device configured to transfer heat to a fluid, where the cooling device is characterized by at least two thermally conductive planes defining a channel for flow of the fluid, and where the material associated with the at least two thermally conductive planes is capable of transferring thermal energy to the fluid through the channel. The device can also include a heat pipe in direct thermal contact with the heat plane. Consistent with this disclosure, one of the at least two thermally conductive planes is aligned with and in direct thermal contact the heat plane, and another of the at least two thermally conductive planes is in direct thermal contact with the heat pipe.

### CROSS-REFERENCE TO RELATED APPLICATIONS

This application is the national stage entry of International Patent Application No.

PCT/US2023/077386, filed on Oct. 20, 2023, and published as WO/2024/086772 A 1 on Apr. 25, 2024, which claims the benefit of U.S. Provisional Application No. 63/380,381, filed on Oct. 20, 2022, which are hereby incorporated by reference in their entireties.

### FIELD

Systems, devices, materials, components, and methods consistent with the present disclosure are directed to temperature control using layered micro-channel devices, systems, and methods.

### BACKGROUND

Layered micro-channel devices, systems, and methods, used for cooling, are disclosed, for example, in U.S. Pat. Nos. 10,379,582 and 11,327,540, the contents of each of which are herein incorporated by reference in their entirety.

When used to cool devices and systems which generate heat in a single plane, for example, there is a need to distribute the full cooling capacity of the layered micro channel device to the single plane.

### SUMMARY

In one aspect, embodiments consistent with the present disclosure provide for extended thermal transfer from a heat plane. Consistent with this disclosure, a device can include at least one cooling device configured to transfer heat to a fluid, where the cooling device is characterized by at least two thermally conductive planes defining a channel for flow of the fluid, and where the material associated with the at least two thermally conductive planes is capable of transferring thermal energy to the fluid through the channel. The device can also include a heat pipe in direct thermal contact with the heat plane. Consistent with this disclosure, one of the at least two thermally conductive planes is aligned with and in direct thermal contact the heat plane, and another of the at least two thermally conductive planes is in direct thermal contact with the heat pipe.

In a further aspect, an embodiment consistent with this disclosure can include at least one cooling device configured to transfer heat to a fluid, where the cooling device is characterized by at least two thermally conductive planes defining a channel for flow of the fluid, where material associated with the at least two thermally conductive planes is capable of transferring thermal energy to the fluid through the channel, and where the channel includes an inlet portion and an outlet portion. The device can further include at least two heat pipes, where each of the heat pipes is in direct thermal contact with the heat plane. Consistent with an embodiment, one of the at least two thermally conductive planes can be in direct thermal contact with at least one of the at least two heat pipes, and another of the at least two thermally conductive planes is in direct thermal contact with another of the at least two heat pipes. Furthermore, consistent with an embodiment, the heat plane can be substantially parallel to a cross section of the channel, and the inlet region can be proximal to the heat plane.

Additional features and embodiments of the invention will be set forth in part in the description which follows, and in part will be obvious from the description, or may be learned by practice of the invention. It is to be understood that both the foregoing general description and the following detailed description are exemplary and explanatory only and are not restrictive of the claimed subject matter.

### BRIEF DESCRIPTION OF THE DRAWINGS

The accompanying drawings, which are incorporated in and constitute a part of this specification, illustrate exemplary embodiments and together with the description, serve to explain the principles of the disclosure. In the figures:

FIGS. 1-5 depict aspects of an embodiment of a system for cooling consistent with this disclosure;

FIGS. 6-10 depict aspects of another embodiment of a system for cooling consistent with this disclosure;

FIG. 11 depicts computed results associated with the embodiments of FIGS. 1-10;

FIGS. 12-14 depict aspects of a further embodiment of a system for cooling consistent with this disclosure;

FIG. 15 depicts a portion of the embodiment of FIGS. 12-14;

FIGS. 16-17 depict aspects of an additional embodiment consistent with this disclosure;

FIG. 18 depicts the embodiments of FIGS. 16-17 used in a server environment; and

FIG. 19 depicts the embodiment of FIG. 18 assembled as an enclosure.

### DESCRIPTION OF THE EMBODIMENTS

Reference will now be made in detail to the depicted embodiments of the disclosure, examples of which are illustrated in the accompanying drawings. Wherever possible, the same reference numbers will be used throughout the drawings to refer to the same or like parts.

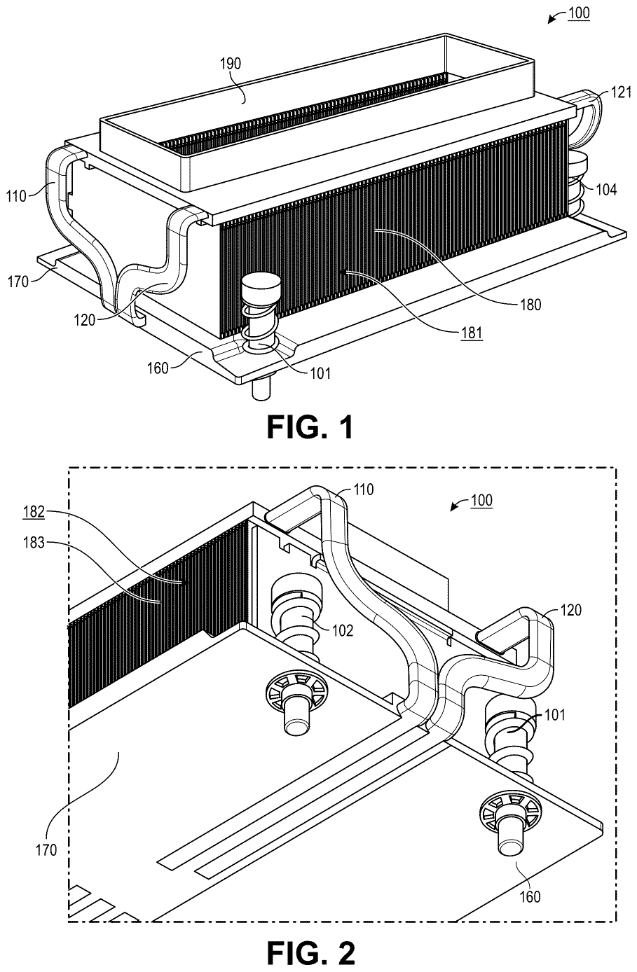

FIGS. 1 and 2 depict an embodiment of a device 100 for cooling a planar region using layered micro channel devices 181 and 182. Layered micro channel devices 181 and 182 (as well as other layered micro channel devices discussed herein, for example) can include stacks of blades (or folded sheets forming a stack of blades) as disclosed in U.S. Pat. Nos. 10,379,582 and 11,327,540. Consistent with this disclosure, a stack of blades can include an alternating stack of first and second blades, including 100, 200, 400, 800, or 1000 or more blades (or any number less than 100, between 100 and 1,000, or more than 1000 blades) where, in an alternating configuration, a stack of 1000 blades can include 500 first blades and 500 second blades. Further still, the “stack” of blades can be formed by a folded sheet, where each alternating fold corresponds to the first blade or a second blade. In a folded sheet embodiment, one fold can form two blades, two folds can form three blades, three folds can form four blades, etc. Moreover, the stack of blades (or folds forming a stack) can be configured such that the spacing between blades (or folds) is less than approximately one of a set of values consisting of: 0.5 mm, 0.45 mm, 0.4 mm, 0.39 mm, 0.38 mm, 0.37 mm 0.36 mm, 0.35 mm, 0.34 mm, 0.33 mm, 0.32 mm, 0.31 mm, 0.3 mm, 0.29 mm, 0.28 mm, 0.27 mm 0.26 mm, 0.25 mm, 0.24 mm, 0.23 mm, 0.22 mm, 0.21 mm, 0.2 mm, 0.19 mm, 0.18 mm, 0.17 mm 0.16 mm, 0.15 mm, 0.14 mm, 0.13 mm, 0.12 mm, 0.11 mm, 0.1 mm, 0.09 mm, 0.08 mm, 0.07 mm 0.06 mm, 0.05 mm, 0.04 mm, 0.03 mm, 0.02 mm, and 0.01 mm.

One of ordinary skill in the art will appreciate, for example, that layered micro channel device 181 can allow a fluid (such as a gas, or air) to pass from region 180 into chimney 190. Layered micro channel device 182 can also allow a fluid to pass from a corresponding region 183 (from the side of device 100 opposite to region 180), to similarly pass into the chimney 190. Consistent with the disclosure, a low pressure can be introduced proximal to the chimney 190 in order to induce fluid flow (for example) from region 180 through layered micro channel device 181 to chimney 190.

FIG. 2 is a bottom perspective of device 100, relative to FIG. 1, and depicts vapor chamber 170 and vapor chamber 160. The plane determined by vapor chamber 160 and vapor chamber 170 is the planar region where heat is expected to be generated or sourced. In one embodiment, for example, device 100 can be used to cool a microprocessor or CPU mounted on a PCB. Mounting bolts 101, 102, 103, and 104 can be dimensioned and configured to couple (for example) with an AMD SP3 socket, or any other suitable socket, device, or component to be cooled.

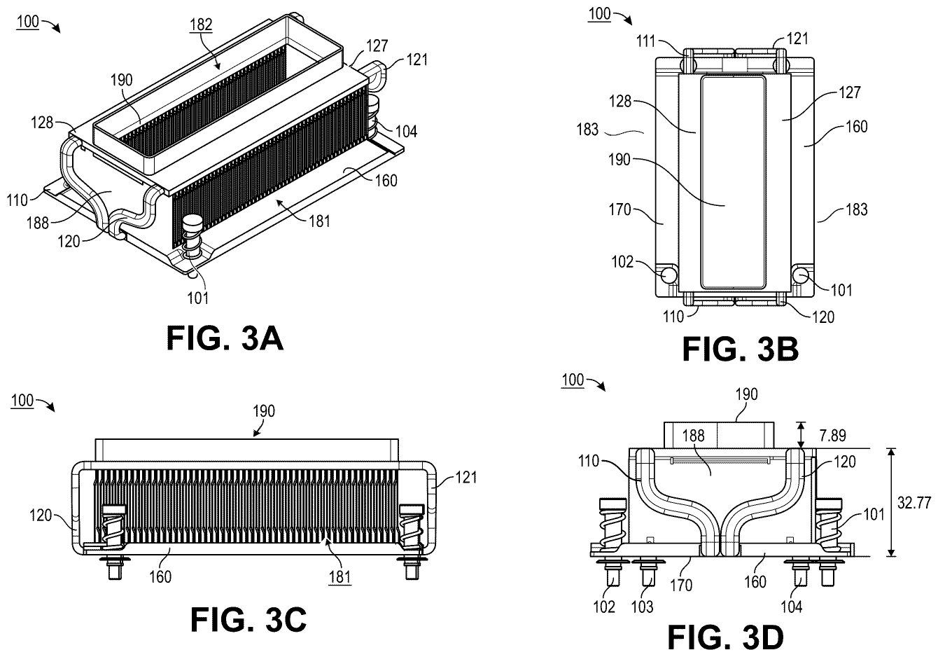

As depicted in FIGS. 1 and 2, a fluid (such as air) can pass from region 183 through layered micro channel device 182 to chimney 190. The portion of layered micro channel device 182 proximal to region 183 is, accordingly, a fluid inlet region. Not shown in FIGS. 1 and 2, layered micro channel device 182 includes a first edge region (or first planar region) in thermal contact with vapor chamber 170. There is also a second edge region (or second planar region) of layered micro channel device 182 which is opposite the first edge region (the first planar region) discussed above. The second edge region (or second planar region) of layered micro channel device 182 is in thermal contact with portions of heat pipe 110 and heat pipe 111 that are configured along the “top” of FIG. 2. Referring to FIGS. 3A and 3B, the portions of heat pipe 110 and 111 in thermal contact with the second edge region (or second planar region) of layered micro channel device 182 are the portions proximal to plate 128.

Accordingly, consistent with this disclosure, layered micro channel device 182 is characterized by a first planar region and a second planar region, each of which include thermally conductive material, and which defines a channel for the flow of fluid (from region 183 to chimney 190). The first planar region is in thermal contact with the vapor chamber 170, and the second planar region is in thermal contact with heat pipe 110 and heat pipe 111.

Similarly, as depicted in FIGS. 1 and 2, a fluid (such as air) can pass from region 180 through layered micro channel device 181 to chimney 190. The portion of layered micro channel device 181 proximal to region 180 is, accordingly, a fluid inlet region. Not shown in FIGS. 1 and 2, layered micro channel device 181 includes a first edge region (or first planar region) in thermal contact with vapor chamber 160. There is also a second edge region (or second planar region) of layered micro channel device 181 which is opposite the first edge region discussed above. The second edge region (or second planar region) of layered micro channel device 181 is in thermal contact with portions of heat pipe 120 and heat pipe 121 along the “top” of FIG. 2. Referring to FIGS. 3A and 3B, the portions of heat pipe 120 and 121 in thermal contact with the second edge region (or second planar region) of layered micro channel device 182 are the portions proximal to plate 127.

Accordingly, consistent with this disclosure, layered micro channel device 181 is characterized by a first planar region and a second planar region, each of which include thermally conductive material, and which defines a channel for the flow of fluid (from region 180 to chimney 190). The first planar region is in thermal contact with the vapor chamber 160, and the second planar region is in thermal contact with heat pipe 120 and heat pipe 121.

FIGS. 3C and 3D provide other perspective views of device 100 disclosed herein.

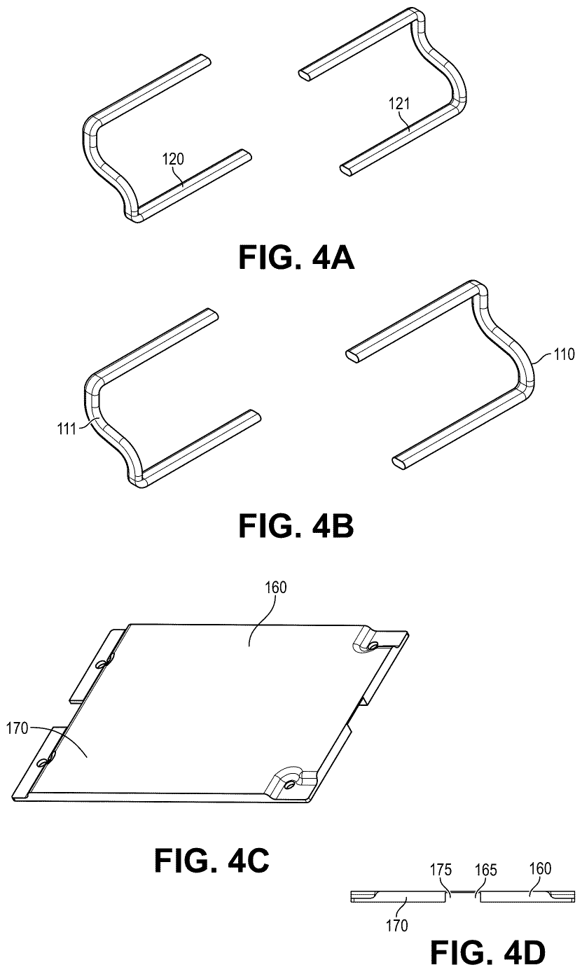

FIGS. 4A-4D provide separate views of heat pipe 120, heat pipe 121, heat pipe, 110, heat pipe 111, vapor chamber 160, and vapor chamber 170. Each of the components depicted in FIGS. 4A-4D can be constructed of materials selected from: copper, nickel-coated copper, and aluminum. Moreover, each component (i.e., heat pipe 120, heat pipe 121, heat pipe, 110, heat pipe 111, vapor chamber 160, and vapor chamber 170) preferably includes a hollow region, at a vacuum, with an amount of vapor, as may be conventionally manufactured consistent with vapor chambers. One of ordinary skill in the art would appreciate, for example, that the sealed vapor chamber in each of the components of FIGS. 4A-4B assist in distributing heat that may be sourced proximal to the plane defined by vapor chamber 160 and vapor chamber 170.

Also depicted in FIG. 4D are slots 175 and 165, configured to accommodate portions of heat pipe 120 (slot 175) proximal to vapor chamber 170, and to accommodate portions of heat pipe 110 (slot 165) proximal to vapor chamber 160. Similarly situated slots are available from the opposite end of vapor chamber 170 and 160, configured to accommodate portions of heat pipe 121 and 111, respectively.

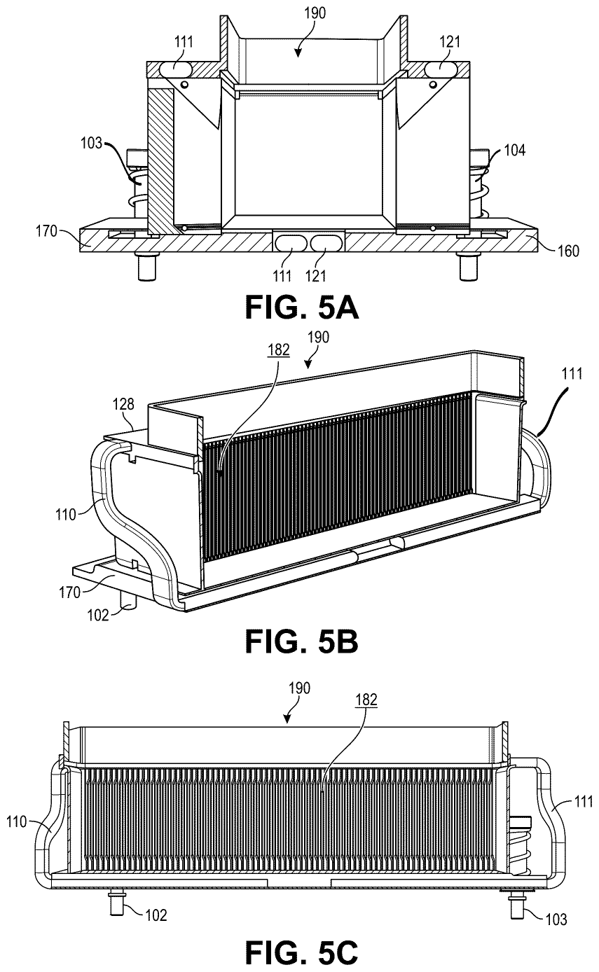

FIGS. 5A-5C depict “cut-open” views of device 100 consistent with this disclosure. Shown in FIG. 5A are the closed ends of heat pipe 111 and heat pipe 121 situated in their respective slots on vapor chamber 170 and vapor chamber 160, respectively. FIGS. 5B and 5C provide open views of chimney 190, and also depict the “exhaust” portion of layered micro channel device 182 (which feeds into the chimney 190). Also labeled in FIG. 5B is a portion of plate 128, which is in thermal contact with portions of heat pipe 110 and heat pipe 111, and also in thermal contact with the second edge of layered micro channel device 182.

Consistent with this disclosure, one principal of operation associated with device 100 is to use heat pipes 110, 111, 120, and 121 to transfer heat generated in the plane associated with the vapor chambers 160 and 170 to the “top” edge of each of the layered micro channel devices 181 and 182.

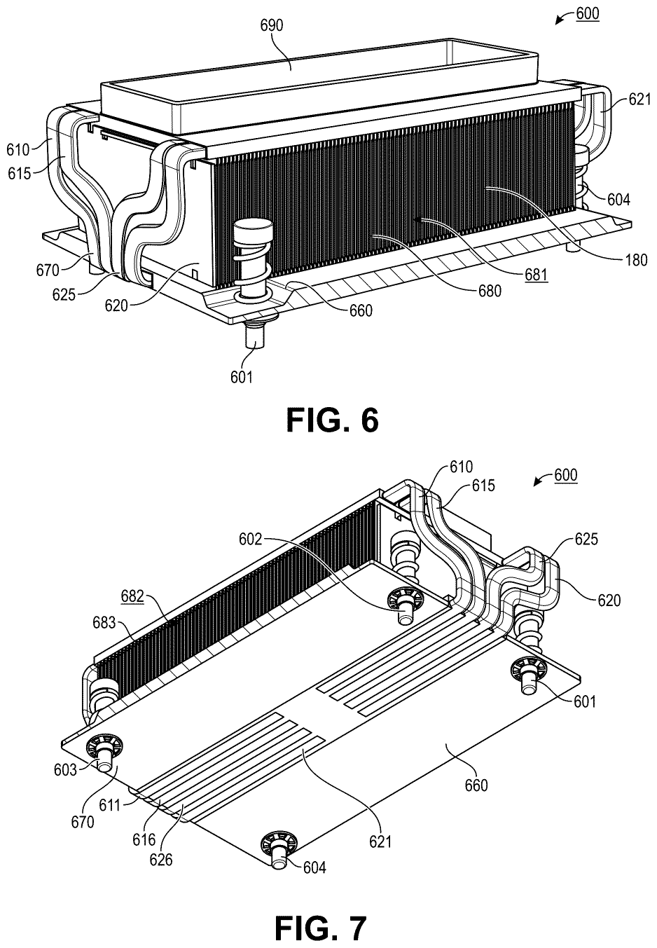

FIGS. 6 and 7 depict a further embodiment of a device 600 for cooling a planar region using layered micro channel devices 681 and 682. Layered micro channel devices 681 and 682 (for example) can include stacks of blades (or folded sheets forming a stack of blades) as discussed earlier. One of ordinary skill in the art will appreciate, for example, that layered micro channel device 681 can allow a fluid (such as a gas, or air) to pass from region 680 into chimney 690. Layered micro channel device 682 can also allow a fluid to pass from a corresponding region 683 from the side of device 600 opposite to region 680, to similarly pass into the chimney 690. Consistent with the disclosure, a low pressure can be introduced proximal to the chimney 690 in order to induce flow (for example) from region 680 through layered micro channel device 681 to chimney 690.

FIG. 7 is a bottom perspective of device 600, relative to FIG. 6, and depicts vapor chamber 670 and vapor chamber 660. The plane determined by vapor chamber 660 and vapor chamber 670 is the planar region where heat is expected to be generated. In one embodiment, for example, device 600 can be used to cool a microprocessor or CPU mounted on a PCB. Mounting bolts 601, 602, 603, and 604 can be configured to couple (for example) with an AMD SP3 socket, or any other suitable socket, device, or component to be cooled.

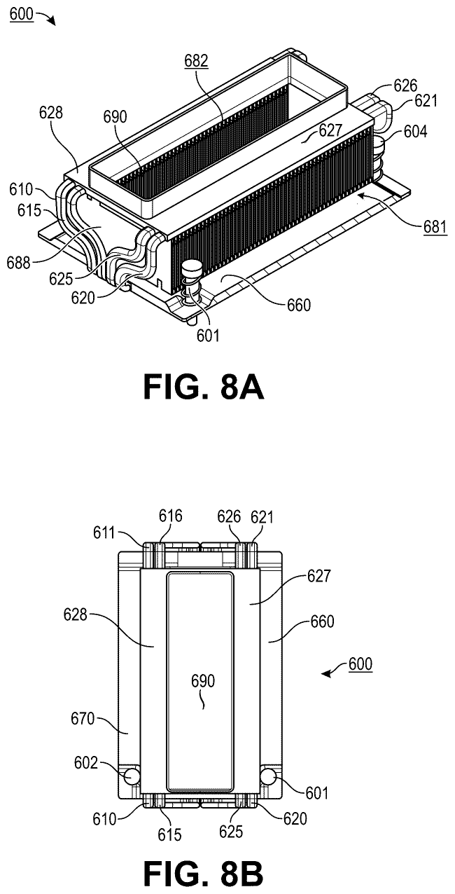

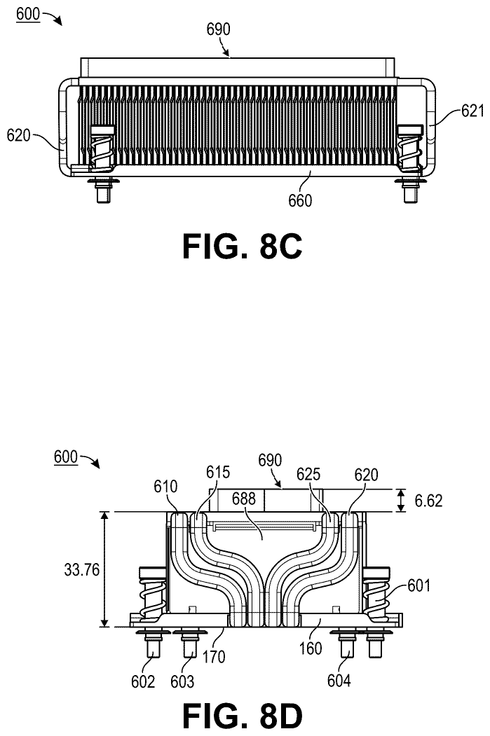

As depicted in FIGS. 6 and 7, a fluid (such as air) can pass from region 683 through layered micro channel device 682 to chimney 690. The portion of layered micro channel device 682 proximal to region 683 is, accordingly, a fluid inlet region. Not shown in FIGS. 6 and 7, layered micro channel device 682 includes a first edge region (or first planar region) in thermal contact with vapor chamber 670. There is also a second edge region (or second planar region) of layered micro channel device 682 which is opposite the first edge region discussed above. The second edge region (or second planar region) of layered micro channel device 682 is in thermal contact with portions of heat pipe 610, heat pipe 611. Heat pipe 615, and heat pipe 616. Referring to FIGS. 8A and 8B, the portions of heat pipe 610, heat pipe 615, heat pipe 611, and heat pipe 616 in thermal contact with the second edge region (or second planar region) of layered micro channel device 682 are the portions proximal to plate 628.

Accordingly, consistent with this disclosure, layered micro channel device 682 is characterized by a first planar region and a second planar region, each of which include thermally conductive material, and which defines a channel for the flow of fluid (from region 683 to chimney 690). The first planar region is in thermal contact with the vapor chamber 670, and the second planar region is in thermal contact with heat pipes 610, 615, 611, and 616.

Similarly, as depicted in FIGS. 6 and 7, a fluid (such as air) can pass from region 680 through layered micro channel device 681 to chimney 690. The portion of layered micro channel device 681 proximal to region 680 is, accordingly, a fluid inlet region. Not shown in FIGS. 6 and 7, layered micro channel device 681 includes a first edge region (or first planar region) in thermal contact with vapor chamber 660. There is also a second edge region (or second planar region) of layered micro channel device 681 which is opposite the first edge region discussed above. The second edge region (or second planar region) of layered micro channel device 681 is in thermal contact with portions of heat pipe 620, heat pipe 625, heat pipe 621, and heat pipe 626. Referring to FIGS. 8A and 8B, the portions of heat pipe 620 and 621 in thermal contact with the second edge region (or second planar region) of layered micro channel device 682 are the portions proximal to plate 627.

Accordingly, consistent with this disclosure, layered micro channel device 681 is characterized by a first planar region and a second planar region, each of which include thermally conductive material, and which defines a channel for the flow of fluid (from region 680 to chimney 690). The first planar region is in thermal contact with the vapor chamber 660, and the second planar region is in thermal contact with heat pipes 620, 625, 621, and 626.

FIGS. 8C and 8D provide other perspective views of device 600 disclosed herein.

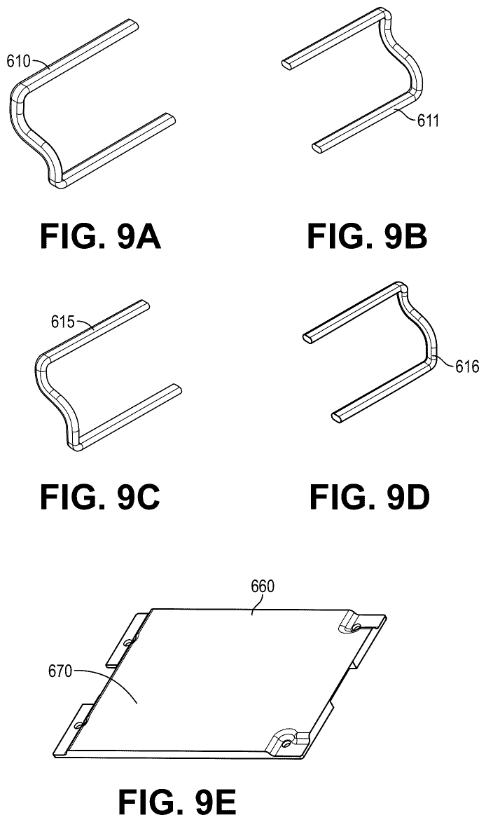

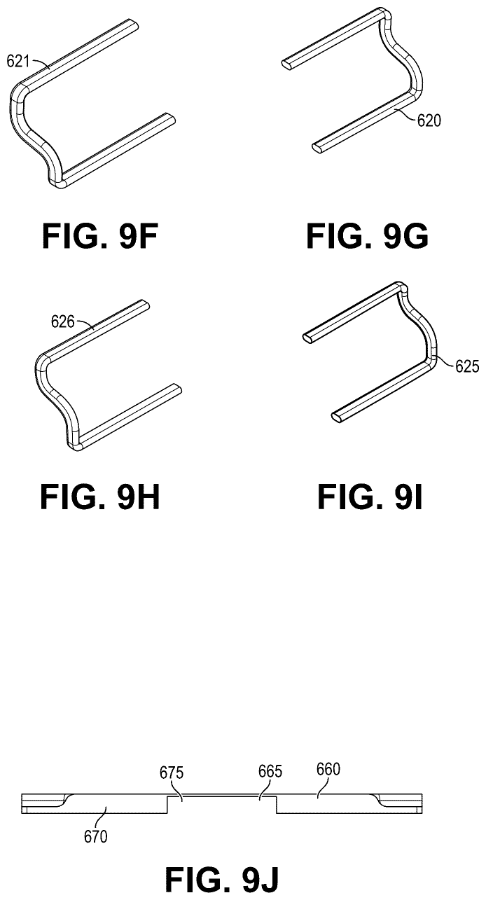

FIGS. 9A-9J provide separate views of heat pipe 610, heat pipe 611, heat pipe 615, heat pipe 616, heat pipe 620, heat pipe 621, heat pipe 625, heat pipe 626, vapor chamber 660, and vapor chamber 670. Each of the components depicted in FIGS. 9A-9J can be constructed of materials selected from: copper, nickel-coated copper, and aluminum. Moreover, each component (i.e., heat pipe 610, heat pipe 611, heat pipe 615, heat pipe 616, heat pipe 620, heat pipe 621, heat pipe 625, heat pipe 626, vapor chamber 660, and vapor chamber 670) preferably includes a hollow region, at a vacuum, with an amount of vapor, as may be conventionally manufactured consistent with vapor chambers. One of ordinary skill in the art would appreciate that the sealed vapor chamber in each of the components of FIGS. 9A-9J can assist in distributing heat that may be sourced proximal to the plane defined by vapor chamber 160 and vapor chamber 670.

Also depicted in FIGS. 9E and 9J are slots 675 and 665, configured to accommodate portions of heat pipe 610 and heat pipe 615 (slot 675) proximal to vapor chamber 670, and to accommodate portions of heat pipe 620 and heat pipe 625 (slot 665) proximal to vapor chamber 660. Similarly situated slots are available on the opposite end of vapor chamber 670 and 660, configured to accommodate portions of heat pipes 611 and 616, and heat pipes 621 and 626, respectively.

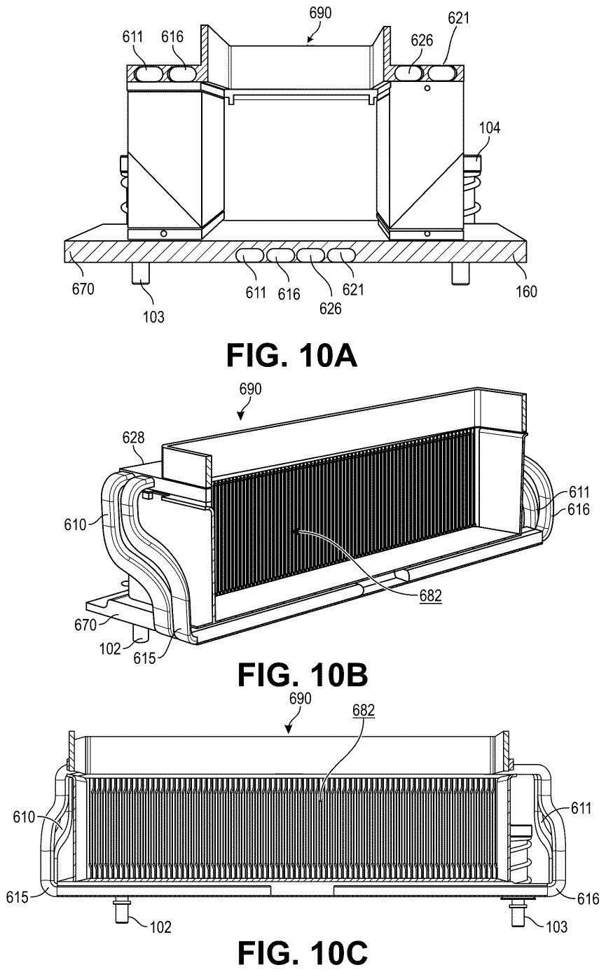

FIGS. 10A-10C depict “cut-open” views of device 600 consistent with this disclosure. Shown in FIG. 10A are the closed ends of heat pipes 611 and 616, and heat pipes 621 and 626 situated in their respective slots on vapor chamber 670—and vapor chamber 660, respectively. FIGS. 10B and 10C provide open views of chimney 690, and also show the “exhaust” portion of layered micro channel device 682 (which feeds into the chimney 690). Also labeled in FIG. 10B is a portion of plate 628, which is in thermal contact with portions of heat pipes 610 and 615 and heat pipes 611 and 616, and also in thermal contact with the second edge of layered micro channel device 682.

Consistent with this disclosure, one principal of operation associated with device 600 is to use a plurality of heat pipes 610, 611, 615, 616, 620, 621, 625, and 626 to transfer heat generated in the plane associated with the vapor chambers 660 and 670 to the “top” edge of each of the layered micro channel devices 681 and 682.

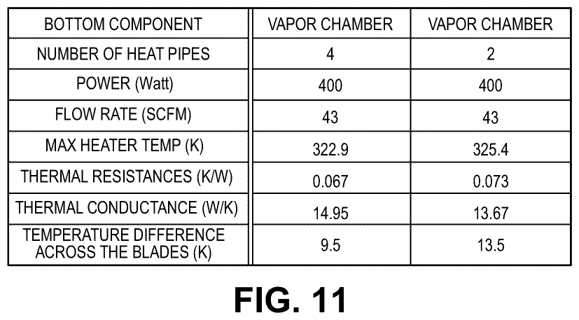

FIG. 11 provides computed results associated with the embodiments of FIGS. 1-10.

Specifically, the embodiment that is associated with “2” heat pipes (third column of FIG. 11) is the embodiment of FIGS. 1-5, and the embodiment that is associated with “4” heat pipes (second column of FIG. 11) is the embodiment of FIGS. 6-10. The row “Temperature difference across the blades” associated with the “4” heat pipe embodiment refers to the temperature difference between the first edge region and the second edge region (or the first planar region and the second planar region) of each of the layered micro channel devices 681 and 682. Essentially, it is the temperature difference across a cross section of the fluid flow through devices 681 and 682. Likewise, the row “Temperature difference across the blades” associated with the “2” heat pipe embodiment refers to the temperature difference between the first edge region and the second edge region (or the first planar region and the second planar region) of each of the layered micro channel devices 181 and 182. Again, it is essentially the temperature difference across a cross section of the fluid flow through devices 181 and 182. As depicted in FIG. 11, the use of additional heat pipes has the effect of decreasing the temperature differential across a cross-section of the fluid flow.

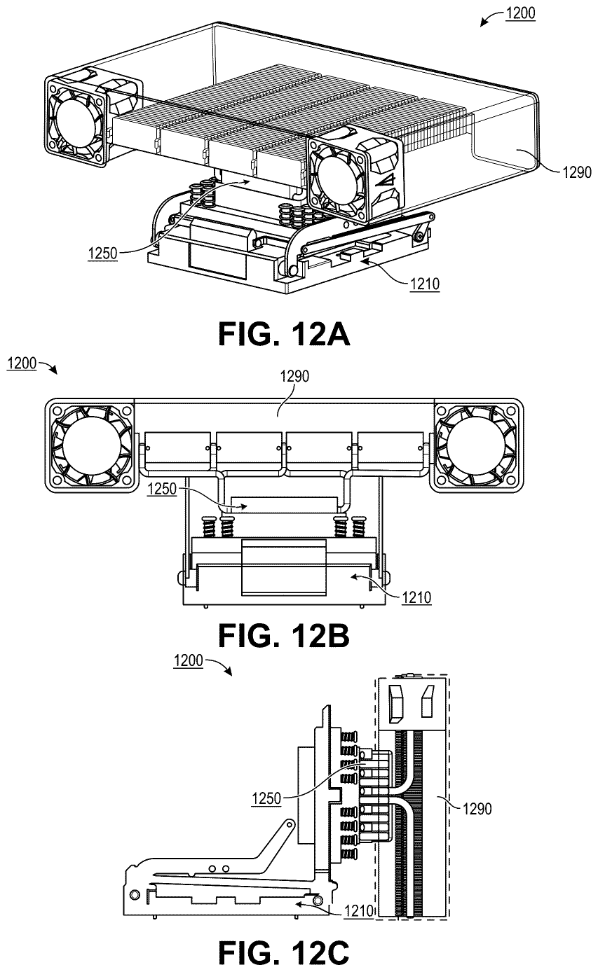

FIGS. 12A-12C depict a further embodiment consistent with this disclosure. Device 1200 includes a test socket 1210, a plenum 1290, and device 1250. Test socket 1210 is a test socket for microprocessors. In FIGS. 12A and 12B, the test socket 1210 is closed, and in FIG. 12C, the test socket 1210 is open.

The plane associated with the heat source in FIGS. 12A-12B is the plane associated with the top portion of test socket 1210.

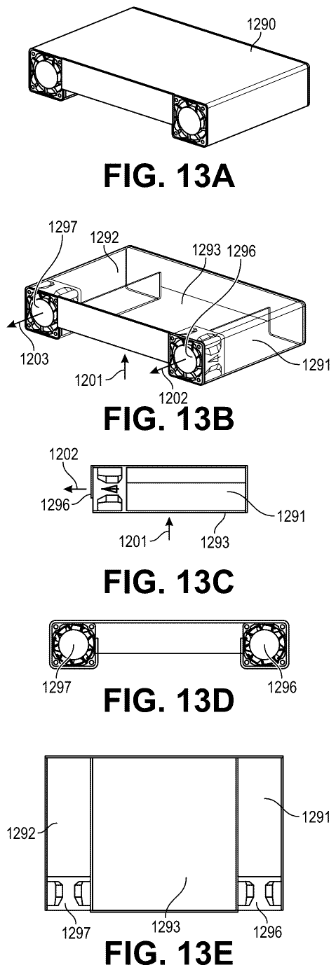

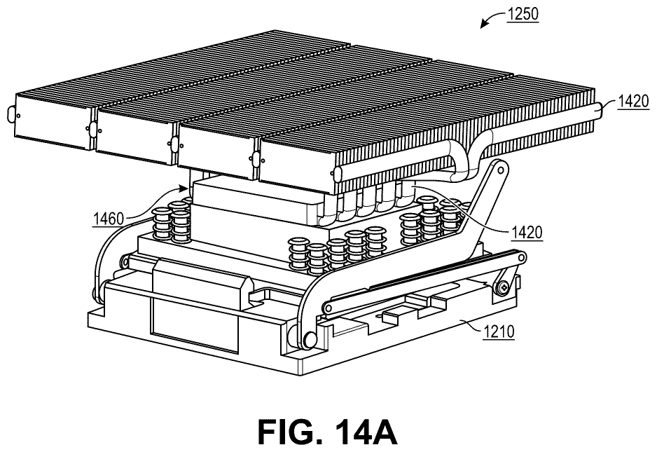

Plenum 1290 is depicted in further detail in FIGS. 13A-13E. FIG. 13A depicts plenum 1290 as viewed from outside the structure. FIG. 13B depicts a cut-away view of plenum 1290, and depicts first exhaust region 1291, second exhaust region 1292, and inflow region 1293. Arrow 1201 and arrows 1202 and 1203 depict, generally, the flow of a fluid (such as air) through plenum 1290. Specifically, a fluid can be drawn into plenum 1290 into region 1293 (as discussed further below). This can be accomplished by introducing a slight low pressure (for example) in exhaust region 1291 and exhaust region 1292, such as by using fans. Outflow regions 1296 and 1297 are also depicted.

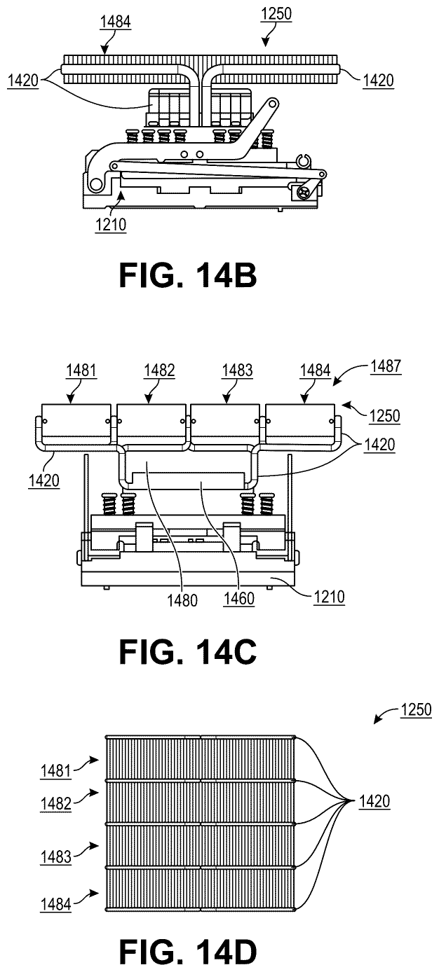

Unlike the embodiments of FIGS. 1-10, the device 1250 incorporates a plurality of elevated layered micro channel devices. This is depicted in FIGS. 14A-14D. As was shown in FIGS. 12A and 12B, test socket 1210 is depicted in a closed configuration. FIG. 14D provides a “top” view, and shows four layered micro channel devices 1481, 1482, 1483, and 1484. Layered micro channel devices 1481, 1482, 1483, and 1484 (for example) can include stacks of blades (or folded sheets forming a stack of blades) as discussed earlier. Unlike the embodiments of FIGS. 1-10, where the fluid inlets into the layered micro channel devices were situated to the sides of the device 100 and 600 (and the fluid outlet was the chimney 190 and 690, respectively), the fluid inlet for the device 1250 is in the region 1480 between a vapor chamber 1460 (or plurality of vapor chambers 1460) and the “bottom” of the layered micro channel devices 1481, 1482, 1483, and 1484. The fluid outlet lies “above” the layered micro channel devices 1481, 1482, 1483, and 1484. Each of the layered micro channel devices 1481, 1482, 1483, and 1484 is configured to allow fluid to flow from region 1480 to region 1487.

Returning to FIG. 12, when plenum 1290 is situated over the layered micro channel devices 1481, 1482, 1483, and 1484, then introducing a lower pressure in the exhaust regions 1291 and 1292 will induce the flow of fluid (such as air) from the region 1480 to 1487.

As stated earlier, the plane associated with the source of heat is the “top” portion of test socket 1210. As depicted in FIG. 14C, a vapor chamber 1460 (or plurality of vapor chambers 1460) can be affixed or adhered to this region, and therefore be in thermal contact with the “top” of test socket 1210. In addition, as also depicted in FIGS. 14A-14D, a plurality of heat pipes 1420 are in thermal contact both with the “top” of test socket 1210 and with the vapor chamber(s) 1460. As depicted further below, and as generally shown in FIGS. 14A-14D, the plurality of heat pipes 1420 elevate and support the plurality of layered micro channel devices 1481, 1482, 1483, and 1484. Moreover, as shown in FIGS. 14A-14D, each of the plurality of heat pipes 1420 lies along either a first edge or a second edge of one of the plurality of layered micro channel devices 1481, 1482, 1483, and 1484. Moreover, a subset of the plurality of heat pipes 1420 can be configured to lie along, both, the first edge of one layered micro channel device (say device 1482) and also along the second edge of another layered micro channel device (say device 1481). In this way, heat from the plane determined by the vapor chamber(s) 1460 can be distributed to the edges of the plurality of layered micro channel devices 1481, 1482, 1483, and 1484.

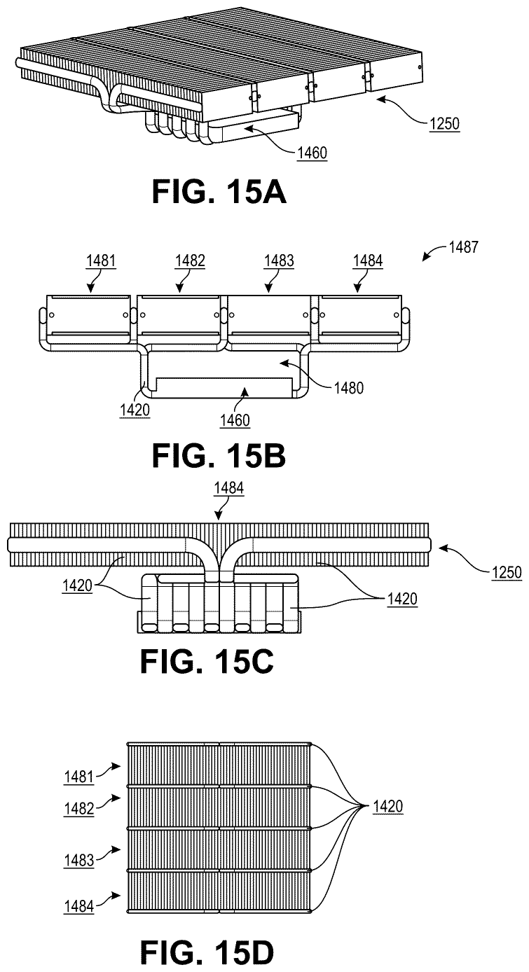

FIGS. 15A-15D provide further views of device 1250 without test socket 1210.

One of ordinary skill in the art will appreciate that the device 1200 (which includes test socket 1210, plenum 1290, and device 1250, can be configured such that test socket 1210 can be opened to allow for insertion of a microprocessor (as shown in FIG. 12C). That is, the extent of the plurality of layered micro channel devices 1481, 1482, 1483, and 1484 and plenum 1290 do not obstruct a (for example) 90-degree “open” configuration for test socket 1210.Although the configuration associated with the plurality of layered micro channel devices 1481, 1482, 1483, and 1484 in FIGS. 12A-12B, 14A-14D, and FIGS. 15A-15D are depicted as supporting an approximately “square” area, one of ordinary skill in the art will appreciate that other, non-square, configurations are also possible. Further still, although FIGS. 12A-12B and 14A-14D depicted device 1250 adhered to (or otherwise in thermal contact with) test socket device 1210, one of ordinary skill in the art will appreciate that device 1250 does not have to be used with a test socket. Rather, device 1250 can be directly adhered to, or otherwise configured, such that vapor chamber 1460 is in thermal contact with the top of a microprocessor (which defines the plane associated with the source of heat).

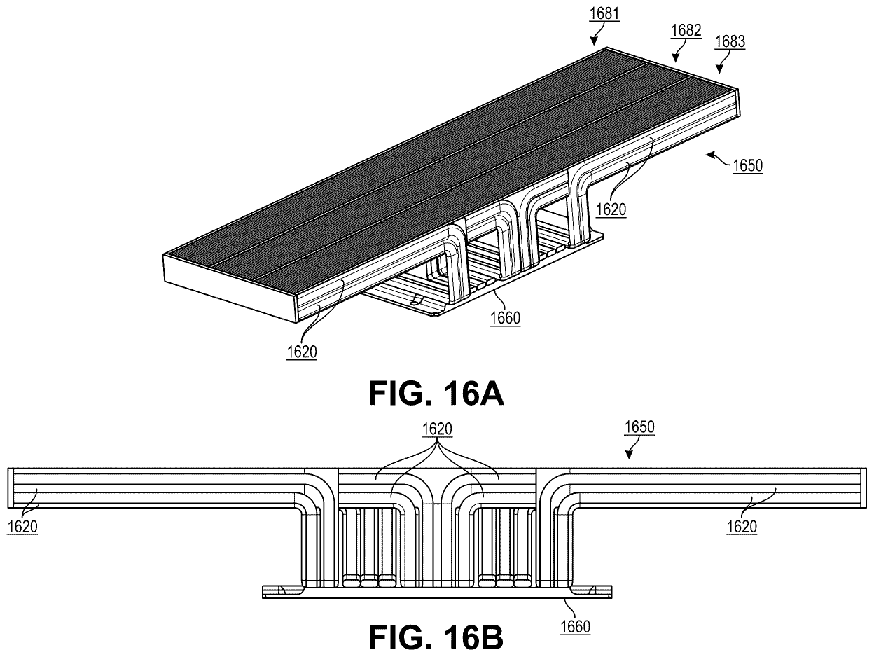

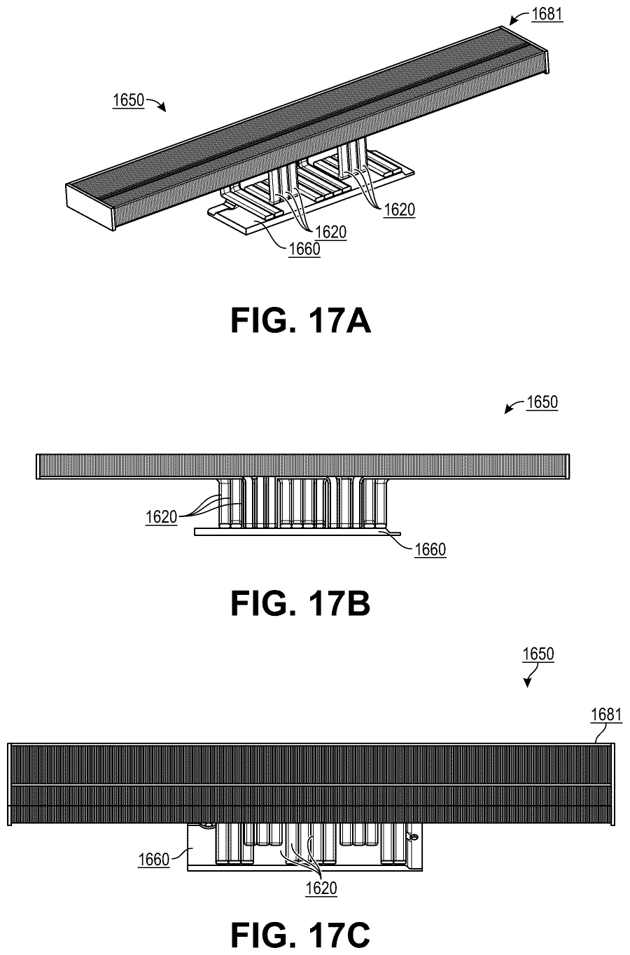

FIGS. 16 and 17 depict a further embodiment, device 1650, consistent with an elevated embodiment, and which includes a generally rectangular area for the plurality of layered micro channel devices 1681, 1682, and 1683. Layered micro channel devices 1681, 1682, and 1683 (for example) can include stacks of blades (or folded sheets forming a stack of blades) as discussed earlier. A plurality of heat pipes 1620 are also depicted as elevated, which both transfer heat from the vapor chamber(s) 1660 and serve to support the plurality of layered micro channel devices 1681, 1682, and 1683. FIG. 16B provides a side view, FIG. 17A provides a “cut away” view from an angled perspective, FIG. 17 B depicts the “cut-away” view from a side perspective, and FIG. 17C provides a “top” perspective of the “cut-away’ view.

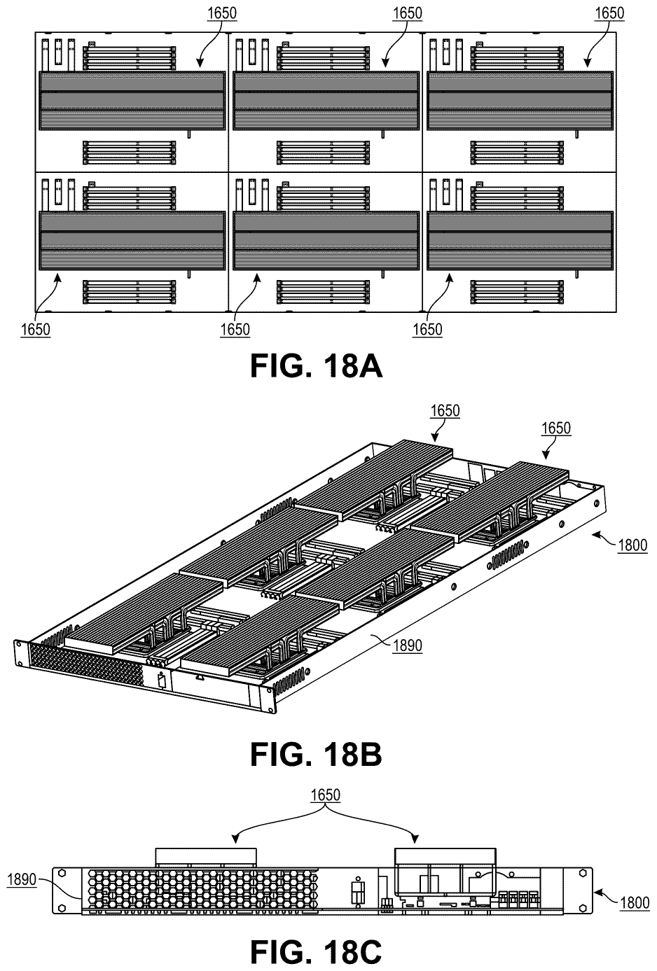

FIGS. 18A-18C provide a view of embodiment 1800, which includes server 1890 and six embodiments consistent with device 1650 adhered to, or otherwise in thermal contact with, 6 CPUs in server 1890.

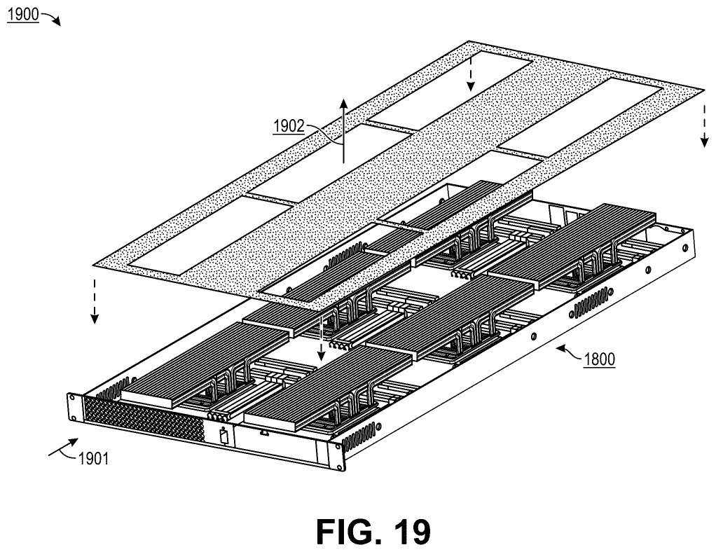

As shown in FIG. 18C, each of the devices 1650 can extend above the tray associated with server 1890. As shown in FIG. 19, this vertical extension of each of the devices 1650 permit the construction of a complete plenum region for device 1800. Specifically, as shown in FIG. 19, enclosure 1900 can include cut-outs for the fluid outlet portion of each of the devices 1650. When enclosure 1900 is affixed over device 1800 then creation of a low pressure region above enclosure 1900 can induce fluid flow (such as air) to follow the path depicted by arrows 1901 and 1902. Specifically, air can enter the device 1800 as indicated by arrow 1901, and when enclosure 1900 is placed over device 1800 then the only available path for air flow (with a low pressure region above enclosure 1900) is through each of the layered micro channel devices 1650.

Although the disclosure utilized layered micro channel devices, one of ordinary skill in the art would appreciate that the configurations disclosed herein can be applied to any device capable of cooling a single planar region where there are at least two planes available for heat transfer to the cooling device.

Other embodiments of the invention will be apparent to those skilled in the art from consideration of the specification and practice of the embodiment disclosed herein. It is intended that the specification and examples be considered as exemplary only, with a true scope and spirit of the invention being indicated by the following claims.

What is claimed is:

1. A device for extended thermal transfer from a heat plane, the device comprising:
at least one cooling device configured to transfer heat to a fluid, wherein said cooling device is characterized by at least two thermally conductive planes defining a channel for flow of said fluid, wherein material associated with said at least two thermally conductive planes is capable of transferring thermal energy to said fluid through said channel; and
at least one heat pipe in direct thermal contact with said heat plane;
wherein one of said at least two thermally conductive planes is aligned with and in direct thermal contact with said heat plane; and
wherein another of said at least two thermally conductive planes is in direct thermal contact with said heat pipe.

2. The device of claim 1, further comprising a second heat pipe in direct thermal contact with said heat plane;
wherein said at least one cooling device includes at least a second cooling device configured to transfer heat to the fluid, wherein said second cooling device is characterized by at least two thermally conductive planes defining a second channel for flow of said fluid, wherein a second material associated with said at least two thermally conductive planes of said second cooling device is capable of transferring thermal energy to said fluid through said second channel;
wherein one of said at least two thermally conductive planes of said second cooling device is aligned with and in direct thermal contact with said heat plane; and
wherein another of said at least two thermally conductive planes of said second cooling device is in direct thermal contact with said second heat pipe.

3. A device for extended thermal transfer from a heat plane, the device comprising:
at least one cooling device configured to transfer heat to a fluid, wherein said cooling device is characterized by at least two thermally conductive planes defining a channel for flow of said fluid, wherein material associated with said at least two thermally conductive planes is capable of transferring thermal energy to said fluid through said channel, and wherein said channel includes an inlet portion and an outlet portion; and
at least two heat pipes, each of said heat pipes in direct thermal contact with said heat plane;
wherein one of said at least two thermally conductive planes is in direct thermal contact with at least one of said at least two heat pipes;
wherein another of said at least two thermally conductive planes is in direct thermal contact with another of said at least two heat pipes; and
wherein said heat plane is substantially parallel to a cross section of said channel, and wherein said inlet region is proximal to said heat plane.

4. The device of claim 1, further comprising a vapor chamber in direct thermal contact with said heat plane;
wherein said vapor chamber is in direct thermal contact with said one of said at least two thermally conductive planes; and
wherein said vapor chamber is in direct thermal contact with said at least one heat pipe.

5. The device of claim 4, wherein said vapor chamber comprises copper.

6. The device of claim 1, wherein said at least one heat pipe comprises copper.

7. The device of claim 1, wherein said fluid is air.

8. The device of claim 1, wherein said heat plane is defined by the surface of a microprocessor.

9. The device of claim 2, further comprising a vapor chamber in direct thermal contact with said heat plane;
wherein said vapor chamber is in direct thermal contact with said one of said at least two thermally conductive planes of said at least one cooling device; and
wherein said vapor chamber is in direct thermal contact with said at least one heat pipe.

10. The device of claim 9, further comprising a second vapor chamber in direct thermal contact with said heat plane;
wherein said second vapor chamber is in direct thermal contact with said one of said at least two thermally conductive planes of said second cooling device; and
wherein said second vapor chamber is in direct thermal contact with said second heat pipe.

11. The device of claim 10, wherein said vapor chamber and said second vapor comprise copper.

12. The device of claim 2, wherein said second heat pipe comprises copper.

13. The device of claim 2, wherein said fluid is air.

14. The device of claim 2, wherein said heat plane is defined by the surface of a microprocessor.

15. The device of claim 3, further comprising a vapor chamber in direct thermal contact with said heat plane;
wherein said vapor chamber is in direct thermal contact with each of said at least two heat pipes.

16. The device of claim 15, wherein said vapor chamber comprises copper.

17. The device of claim 3, wherein each of said at least two heat pipes comprise copper.

18. The device of claim 3, wherein said fluid is air.

19. The device of claim 3, wherein said heat plane is defined by the surface of a microprocessor.

20. The device of claim 3, wherein said heat plane is defined by the surface of a test socket.

21. The device of claim 3, further comprising a plenum enclosing at least a portion of said at least one cooling device;
wherein said plenum comprises at least one exhaust region and an inflow region, wherein said inflow region is proximal to said at least one cooling device;
wherein said plenum is configured such that flow of the fluid can be induced from the inlet region through said at least one cooling device to said inflow region by introducing a lower pressure in said at least one exhaust region.

22. The device of claim 21 further comprising a fan in said at least one exhaust region capable of introducing said lower pressure in said at least one exhaust region.

23. The device of claim 3, further comprising a server including a board including at least one processor, said at least one processor defining said heat plane; and
further comprising a server enclosure configured to fit above said board, and configured with cut-outs such that said at least one cooling device extends above said server enclosure into an enclosure region;
wherein said server enclosure is configured such that flow of the fluid can be induced from the inlet region through said at least one cooling device to said enclosure region by introducing a lower pressure in said enclosure region.
